(19) United States
(12) Patent Application Publication
(10) Pub. No.: US 2014/0197312 A1
(43) Pub. Date: Jul. 17, 2014

(54) ELECTRON MICROSCOPE AND SAMPLE OBSERVATION METHOD

(71) Applicant: Ken Harada, Tokyo (JP)

(72) Inventor: Ken Harada, Tokyo (JP)

(73) Assignee: HITACHI, LTD.

(21) Appl. No.: 14/239,146

(22) PCT Filed: Sep. 30, 2011
(86) PCT No.: PCT/JP2011/005525

§ 371 Date: Mar. 17, 2014

(51) Int. Cl. H01J 37/24; H01J 37/26

(52) U.S. Cl. CPC H01J 37/243; H01J 37/26
USPC 250/307; 250/311

(57) ABSTRACT

The Foucault mode which is one method in Lorentz electron microscopy is required making a plurality of observations such as when reselecting the deflection components of the electron beam to form an image. This method not only required making plurality of adjustments to the optical system but was also incapable of making dynamic observations and real-time observations at different timings even if information on the entire irradiation region was obtained. The present invention irradiates a single electron beam onto the sample, and by utilizing an electron biprism placed such as on an angular space on the electron optics, applies a deflection in the travel direction of each electron beam, and forms the sample image by individually and simultaneously forming images from each of electron beams at different positions on the image surface of the electron optical system.

### TECHNICAL FIELD

The present invention relates to an electron microscope and a sample observation method utilizing the electron microscope.

### BACKGROUND ART

Visualization (imaging) techniques for the electron beam deflection state representative of Lorentz electron microscopy are widely utilized as one technique for observation of information on physical properties of non-biological samples such as for observation of the magnetic distribution in magnetic materials. Lorentz electron microscopy just as the name implies, is a technique developed to observe the state of an electron beam passing through magnetic material deflected by Lorentz force due to the magnetism of the material. Lorentz electron microscopy is broadly grouped into the two modes called the Foucault mode and the Fresnel mode. These methods are each hereafter described using as an example, observation of magnetic material containing a 180 degree inverted magnetic domain structure.

### <Fresnel Mode>

FIG. 1 shows the state where an electron beam is deflected by magnetic material containing a 180 degree inverted magnetic domain structure. The angle at which the electron beam is deflected depends on the size of the magnetization and the thickness of the sample. Therefore, in a sample with a specified thickness and uniform magnetization, the deflection that the electron beam sustains will have the same angle in any region and a different direction according to the magnetic domain structure.

As shown in FIG. 1, when an electron beam 27 is incident on a sample 3 containing a 180 degree inverted magnetic domain structure, the electron beams 27 transmitted through the sample 3 is deflected in directions opposite the respective magnetic domains (31, 33). When the deflected electron beams 27 propagate a certain sufficient distance below the sample, a state occurs where the deflected electron beams mutually overlap, and conversely a state occurs where the deflected electron beams mutually separate at a position equivalent to the 180 degree magnetic domain wall 32 on the projection plane 24. The Fresnel mode is utilized to image the coarse-fine intensity of the electron beam on the projection plane 24. An example of the electron beam intensity distribution on the projection plane is shown in the graph 25 on the lower section of FIG. 1.

FIG. 2 is diagrams showing the optical system during observation of the magnetic sample by the Fresnel mode. A Fresnel image is shown in the lower section of FIG. 2. FIG. 2(a) shows the state where observing while focused at a spatial position 35 on the lower side of the sample, not the state focused at the sample and so is exactly where a section of the magnetic domain wall 32 is observed at a contrast 72 of bright lines (white-color) or dark lines (black-color).

As shown in FIG. 2(b) in the same way, the magnetic domain wall 32 section can be observed at the reverse of the contrast 72 even if the focus is aligned on the spatial position 36 on the sample upper side. In other words, by making the observation while the focus is offset from the sample, the boundary line of the region applying a deflection to the electron beam can be observed at the bright lines (white-color) or dark lines (black-color). The Fresnel mode is the technique used for observing the magnetic domain wall in the case of magnetic material. The monochrome contrast of the boundary lines of the Fresnel mode at this time is dependent on the deflection direction combination and focus position.

The amount of focus offset (defocus quantity) is dependent on the size of the deflection sustained by the electron beam, and in the event of a large deflection, an adequate contrast can be obtained at a small defocus quantity of approximately a few hundred nm. However, a defocus quantity of a few hundred mm is required if for example the object for observation applies only a small deflection such as a flux quantum.

### <Foucault Mode>

FIG. 3 is a drawing of the optical system for observing the magnetic domain structure by way of the Foucault mode. Here, just as in FIG. 1, an electron beam transmitted through a sample 3 having a 180 degree inverted magnetic domain structure is deflected in directions mutually opposite each magnetic domain (31, 33), and the electron beam deflected in that direction, reaches the spots (11, 13) at the position according to the deflection angle for example of the back focal plane 54 (strictly speaking, the image surface of the light source for the irradiated electron beam) of the objective lens 5. The objective aperture 55 is therefore inserted, and an electron beam is selected only from the magnetic domain that must be observed, and the electron beam is then imaged on the image surface 7.

FIG. 3(a) is an example of selecting the electron beam deflected to the left direction on the paper surface after transmitting through the magnetic domain 31, and FIG. 3(b) to the contrary is an example for selecting the electron beam deflected to the right direction on the paper surface after transmitting through the magnetic domain 33. In either case, the selected magnetic domain is observed as a white color and the non-selected magnetic domain as a black color (no electron beam contact), and the magnetic domain structures (31, 33) are imaged as striped-shape (71, 73) Foucault images. The Foucault mode is a technique for observation of magnetic domains for example of magnetic materials.

The Foucault mode can be expected to provide high resolution observation of sample images by in-focusing, however when utilizing magnetic material, the deflection angle of the electron beam is small at approximately 1/10^{th} that of the Bragg angle due to the crystalline material so that an objective aperture having a small diameter opening must be utilized, and the spatial resolution obtained is approximately 1/10^{th} the lattice resolution and so there is no large difference compared to the Fresnel mode. Moreover, the Foucault mode is a technique for obtaining contrast by discarding a portion of the information by blocking the electron beam transmitted through non-observed magnetic domains which are the origin of the contrast for observation in the magnetic domain structure.

Therefore, observing images spanning a plurality of magnetic domains such as crystalline grain boundary required readjusting the objective aperture and separately observing the reverse-contrast Foucault image, or removing the objective aperture from the optical axis and making observations along with a normal electron microscopy image. In other words, making observations a plural number of times was required, and making dynamic observations or real-time observations was virtually impossible.

Though not shown in the drawings, one method proposed for resolving the problems of the Foucault mode is to split the incident electron beam to the sample into plural electron beams by utilizing an electron (beam) biprism in the irradiation optical system, and inputting each of the plurality of electron beams onto the same region on the sample at respectively different incidence angles, and then isolating each of the electron beams transmitted through the sample by way for example of an electron biprism or aperture mechanism, or an imaging optical system including both (electron biprism and aperture mechanism), and simultaneously observing the separate images of the sample by way of the respective electron beams (patent document 1).

However, the patent document 1 was originally designed for the purpose of stereoscopic viewing, and changed the irradiation angle of the two electron beams by utilizing for example an electron biprism. Therefore, the same irradiation conditions are not utilized for the sample so strictly speaking the image is not modulated only by the physical characteristics (assuming mainly magnetism) of the sample. In the case of an equal inclination fringe in particular, the interference fringe is determined by the relation between the incidence angle and the crystalline orientation of the sample so that the need occurs to make the incidence angles the same in order view the equal inclination fringe in the same way.

The addition of another device such as an electron biprism to the irradiation optical system in the upper section of the sample also required so that in the case of an actual experiment, the difficulty occurring in accurately separating the irradiation quantities could be expected to lead to troublesome device operation. Therefore these types of issues with the Foucault mode still remain unresolved.

Besides the above described Lorentz electron microscopy, other techniques developed to observe magnetic domain structures of the sample from the phase distribution of the electron beam include electron beam holography (nonpatent literature 1) or the transport of intensity equation (patent literature 2, nonpatent literature 2), etc. Each technique has its own particular advantages but in view of the fact that electron beams having high interference such as field emission type electron beam are required, and also that an electron biprism is required as an additional device in electron holography; an area must be allowed for on the sample shape to permit reference waves to transmit through. Moreover, the fact that the transport-of-intensity equation requires at least two images (total of three images in some cases) having previously known defocus quantities enclosing the in-focus image, and that adjustment is indispensable for the position alignment and the magnification scale of each image and so on, actually implementing these techniques requires a great deal of trouble.

### CITATION LIST

### Patent Literature

Patent literature 1: Japanese Unexamined Patent Application Publication No. 2011-040217
Patent literature 2: Japanese Unexamined Patent Application Publication No. 2007-134229

### NONPATENT LITERATURE

Nonpatent literature 1: A. Tonomura, J. Electron Microsc. 33 (1984) 101.
Nonpatent literature 2: K. Ishizuka and B. Allman, J. Electron Microsc. 54 (2005) 191.

### SUMMARY OF INVENTION

### Technical Problem

Obtaining information for the entire surface of the region irradiated by the electron beam on the sample required making plural observations such as when reselecting and imaging the electron beam deflection component and so on. This method not only required plural adjustments of the optical system but also making observations at different timings even if information for the entire irradiation area was obtained, so that not only were dynamic observations or real-time observations impossible but making strict observations under identical irradiation conditions was difficult.

### Solution to Problem

The electron microscope of the present invention is featured in including: a light source to generate an electron beam; an irradiation optical system to irradiate a single electron beam emitted from the light source onto the sample; an imaging lens system containing an objective lens and a plurality of lenses to form the image of the sample; an electron biprism to deflect the electron beam after transmitting through the sample in mutually different directions, placed on the downstream side of the electron beam direction of travel from the objective lens, and also mounted in the space in the shadow of an electron beam generated by deflection or diffraction when the electron beam transmits through the sample along the electron beam path; an observation recording surface to observe the image of the sample isolated by the electron biprism; and an image recording device to record the image of the isolated sample.

The sample measurement method of the present invention is an observation method utilizing an electron microscope that includes: a light source to generate an electron beam; an irradiation optical system to irradiate a single electron beam emitted from the light source onto the sample; an imaging lens system containing an objective lens and plural lenses for forming the image of the sample; an electron biprism placed in a space on the downstream side of the electron direction of progress from the objective lens; an observation recording surface to observe the image of the sample; and an image recording device to record the image of the isolated sample, and featured in that the irradiation optical system irradiates a single electron beam emitted from the light source onto the sample; the electron biprism placed in the space in the shadow of an electron beam generated on the path of the electron beam irradiated onto the sample, deflects the electron beams after transmitting through the sample into mutually different directions; the observation recording surface observes the image of the sample isolated by the electron biprism, the image recording device records the image of the sample that was observed, and the electron microscope finds the orientation distribution of the deflection of the electron beam within the sample or the orientation distribution of the diffraction of the electron beam within the sample based on the recorded sample image.

### Advantageous Effects of Invention

The present invention is capable of acquiring image data under completely identical irradiation conditions, and so is not only capable of observing the defection state across the entire observation surface, but also achieving satisfactory dynamic observation and real-time observation.

### BRIEF DESCRIPTION OF DRAWINGS

FIG. 1 is a diagram for showing the state of the deflection when an electron beam transmits through a sample containing inverse magnetic domain structures;

FIG. 2 is a diagram for describing the Lorentz electron microscopy (Fresnel mode);

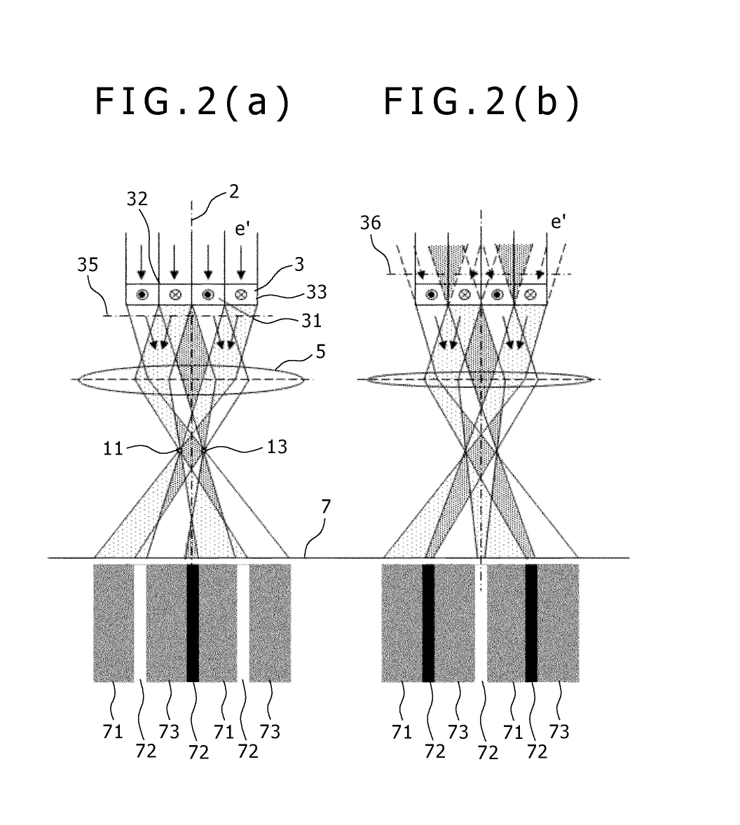

FIG. 3 is a diagram for describing the Lorentz electron microscopy (Foucault mode);

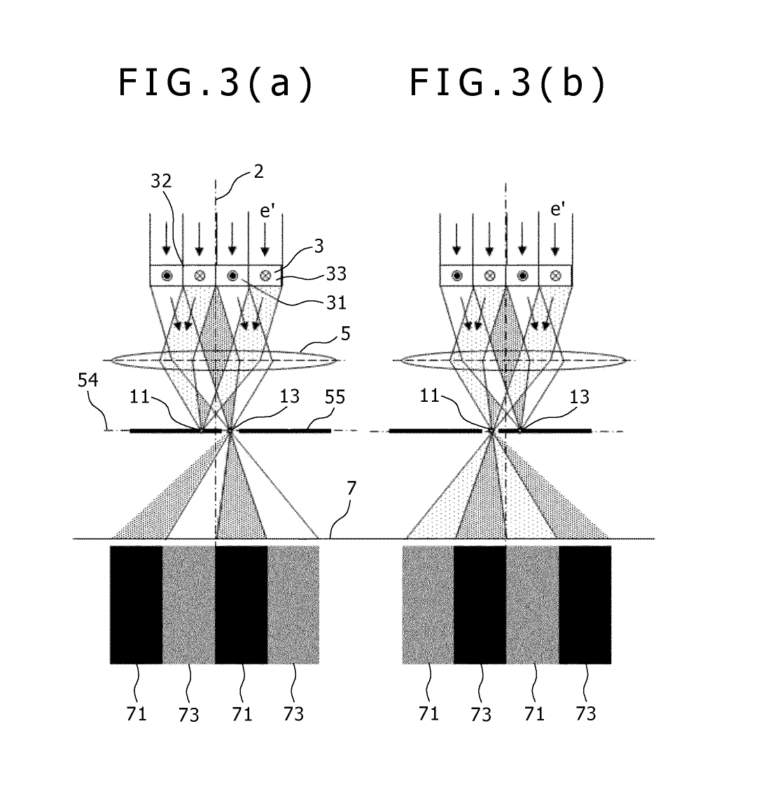

FIG. 4 is a diagram for showing an electron biprism and the deflection of the electron beam by the electron biprism;

FIG. 5 is a diagram of the optical system showing the principle of the present invention;

FIG. 6 is a diagram of the optical system showing the principle of the present invention, and FIG. 6(a) is the case when the voltage applied to the electron biprism is negative; and FIG. 6(b) is the case when the voltage applied to the electron biprism is positive;

FIG. 7 is an illustration of an experimental result showing a light source image for electrons from an objective lens and an image of the center super-fine electrode of the electron biprism;

FIG. 8 is experimental results showing the Foucault image observed when the voltage applied to the electron bi-prism was changed. Here, A is −100 volts, B is −50 volts, C is 0 volts, D is +50 volts, and E is +100 volts;

FIG. 9 is a diagram showing a typical structure of the electron microscope of a second embodiment of the present invention;

FIG. 10 is experimental results showing the arithmetic processing of the Foucault image. Here, A, B are the Foucault image, C, D are the difference image obtained respectively by subtraction processing from A, B;

FIG. 11 is experimental results showing the arithmetic processing of the Foucault image. Here, A is the electron microscope image, B is the overlapping image cumulatively processed from the FIGS. 10A and 10B;

FIG. 12 is a diagram showing the optical system utilizing the square pyramidal electron prism (electron biprism containing two intersecting center super-fine electrodes) of a fourth embodiment of the present invention;

FIG. 13 is a diagram showing a typical structure of the electron microscope of a fifth embodiment of the present invention;

FIG. 14 is a diagram showing the state of the deflection when the electron beam transmits through material containing polarized structures, and the relation between the light source image by the deflected electron beam and the placement, of the electron biprism:

FIG. 15 is a diagram showing the state of diffraction when the electron beam transmits through the crystalline material, and the relation between the light source image by the diffracted electron beam and the placement of the electron biprism;

FIG. 16 is a diagram showing the state of diffraction upon sustaining effects from a strain field when the electron beam transmits through the super-lattice material, and the relation between the light source image by the affected electron beam and the placement of the electron biprism;

### DESCRIPTION OF EMBODIMENTS

### Electron Biprism

In the description of the present invention, an electron biprism is utilized to further deflect the propagation direction of the electron beams after being deflected in several directions and orientations due to the sample, and to spatially separate the image positions of each electron beam. The electron biprism is first of all described.

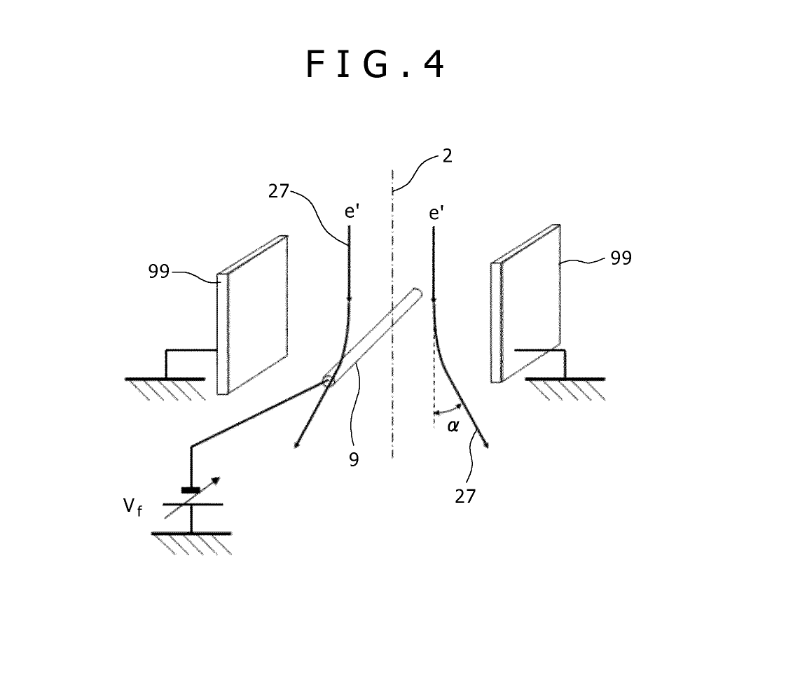

The electron biprism is a device within the electron optical system that renders the same effect as Fresnel's biprism within the optical system, and includes two types one of which is an electric field type and the other is a magnetic field type. Among these types, the most widely utilized type is the (electric) field type electron biprism shown in FIG. 4, and that contains a center super-fine electrode 9, and a pair of parallel-plate grounded electrodes 99 grounded while maintained in parallel enclosing the electrode 9. When for example a negative voltage is applied to the center super-fine electrode 9, the electron beams 27 transmitting through the vicinity of the center super-fine electrode 9 are mutually deflected in separate directions by the voltage potential of this center super-fine electrode 9. Needless to say, the positive/negative voltage applied to the electron biprism can be changed according to the structure of the optical system.

Hereafter, the electron biprism of the present specification is described next by utilizing an electric field type electron biprism. The present invention however can utilize a structure that is not dependent on an electric field type or a magnetic field type as the electron biprism, and is not limited to the electric field type electron biprism used in the following description.

A unique feature of the present invention in an electron optical system having only one optical axis for an electron microscope including one mirror body, is the spatial isolating of the electron beam deflected in respectively different directions and orientations by the magnetic distribution within the sample, and so on during transmitting through the sample, and separately imaging and recording each image as the different images.

The present invention is capable of simultaneously obtaining plural observation images for the same region, increasing the volume of acquired information, and improving the testing efficiency. The method for acquiring the observation images may respectively install devices for capturing images at each location corresponding to the plural observation images, or may process an image captured on one image capture device and extract plural observation images. The difference in effects obtained by the different configurations structures is described in the embodiments.

Moreover, the present invention does not utilize the coherence of the electron beam even if using an electron biprism. Another feature of the present invention is therefore that there is no need for coherency from the optical system to the electron beam as long as the observation target does not require coherence.

The plural images acquired by the present invention are imaged from electron beams transmitting through the sample at exactly the same time so that strict simultaneous observation is achieved. Therefore, restricted only by the time resolution of the observation recording system, the present invention is capable of the same dynamic observation and real-time observation as in ordinary electron microscope observation.

### First Embodiment

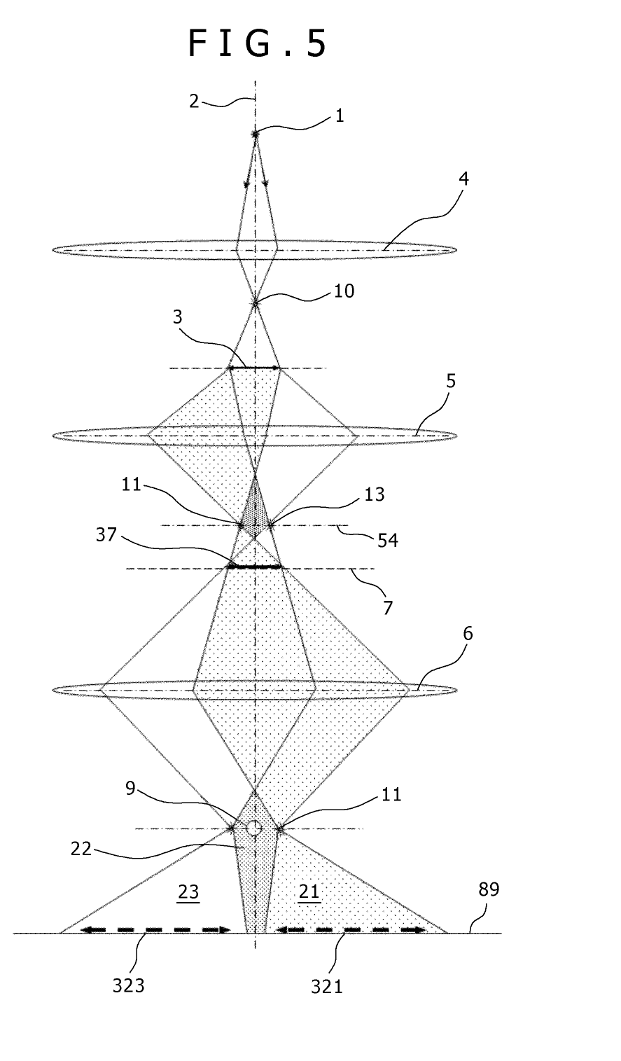

A representative optical system of the present invention is shown as the first embodiment while referring to FIG. 5. The single electron beam emitted from a light source 1 of electrons is adjusted so as to achieve an appropriate electron density and irradiation range during irradiating onto a sample 3 from the irradiation optical system (irradiation lens 4). The electron beam irradiated onto a specified region of the sample 3 is deflected in mainly two different directions for example by the inverse magnetic domain structures within the sample in order to separate the light source image on the upper side of the sample (crossover) 10 into two images (11, 13) of the light source according to each of the deflection directions after transmitting from the objective lens 5.

The electron beam 21 deflected to the left direction along the paper surface within the sample is cross-hatched (section lines) for the purpose of making FIG. 5 easy to understand. An image 37 of the sample 3 by the objective lens 5 is imaged on the observation recording surface 89 by an enlargement imaging system. However, the electron beams (21, 23) respectively deflected in the different directions, are further deflected and spatially separated by the electron biprism 9 mounted in the vicinity of the light source images (11, 13) from the imaging lens 6, and the respective separate images (321, 323) are imaged on the observation recording surface 89.

The method for utilizing the electron biprism 9 of the present invention is therefore essentially different from interference methods such as electron holography, and the electron biprism 9 is utilized in order to spatially separate the electron beams (21, 23) in two directions for the purpose of separately imaging, observing, and recording each of the two images (321, 323). In the case of the interference method, there is restriction that a holograph electron microscope must be utilized however the present specification can be achieved by utilizing an electron microscope of the related art.

FIG. 5 shows an example in which the electron biprism 9 is mounted in the shadow space 22 formed by the imaging lens 6. However, aside from the image surface and object surface of the sample, any position on the optical system may be utilized if a shadow space, and an actual mounting position may be established after considering the mechanical position structure in the electron microscope and other factors. Whatever the position, there must be a space on the electron microscope device allowing mounting from both a spatial and mechanical perspective and the shadow space 22 must be capable of housing the thickness of the center super-fine electrode 9. The size of the shadow space to the contrary becomes smaller as the size of the sample image increases, so the vicinity of the light source image surface 54 from the objective lens 5 is suitable.

To simplify the description for FIG. 5, the devices up to the irradiation optical system such as the accelerating tube and so on are omitted and represented by the electron light source 1, and the irradiation optical system is also represented by one stage irradiation lens 4. Also in the enlargement imaging system, just one stage of each of the objective lens 5 and the imaging lens 6 are given in order to make the concept of the present invention easy to understand. Further, for the electron biprism, the cross-sectional shape of the center super-fine electrode 9 is expressed just by a circle and the ground electrode is omitted. These components were all omitted to prevent the drawings from becoming complicated and do not show the essential substance of the invention. Also, for the electron biprism, the notation “center super-fine electrode for electron biprism” is given strictly for the case where showing the center super-fine electrode within the optical system, and when expressing the deflector for the electron beam is only shown by the notation “electron biprism”; however, the same reference sign 9 or 90 is utilized. Drawings subsequent to FIG. 5 are hereafter expressed in the same way as above.

### Second Embodiment

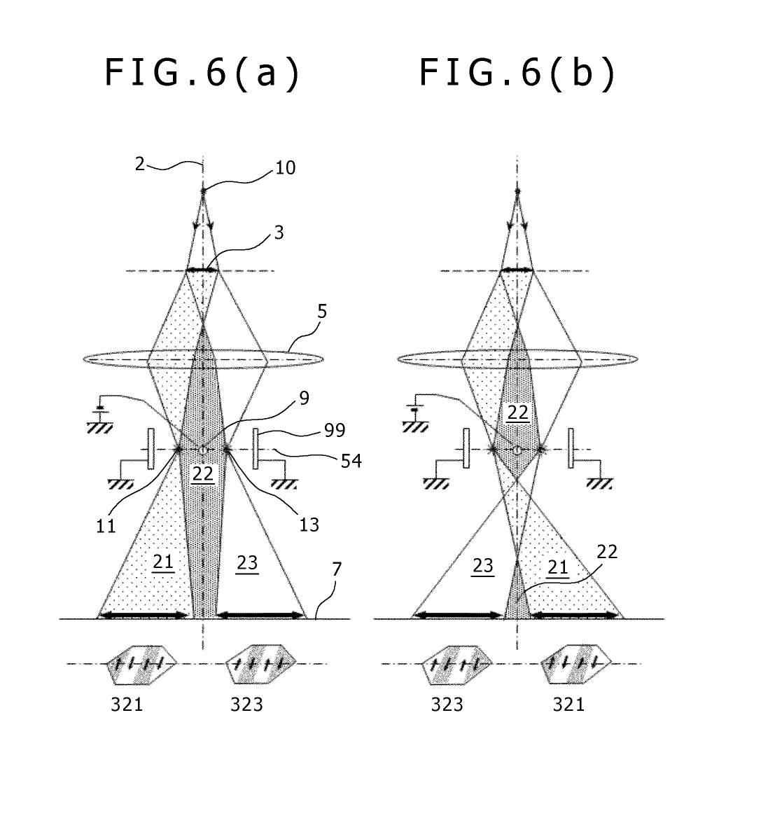

FIG. 6 shows the most simplified optical system as the second embodiment in which the positive-negative voltage applied to the electron biprism has been reversed. In the structure in FIG. 6, the irradiation optical system and the enlargement imaging system are omitted, and only a structure including the light source image 10, the sample 3, the objective lens 5, the electron biprism 9, and the image surface 7 is shown. The sample 3 is a material for deflecting the electron beam in two different directions and for example the use of an inverted magnetic domain structure is assumed.

Therefore, after transmitting through the sample 3, the electron beam is deflected in two directions (21, 23) and each beam forms the respective light source images (crossovers) (11, 13) on the lower side of the objective lens 5. In FIG. 6(a), a negative voltage is applied to the electron biprism 9 and the electron beams (21, 23) from both the crossovers (11, 13) set so as not to overlap. The state of the deflection applied by the electron biprism is the same as in FIG. 5.

In FIG. 6(b) on the other hand, a positive voltage is applied to the electron biprism 9 and deflection is applied so that transposition is completed before propagating of the electron beams (21, 23) from both crossovers (11, 13) on the image surface 7. Hereafter, the same result is obtained just by transposing the two obtained images (321, 323) left and right positions.

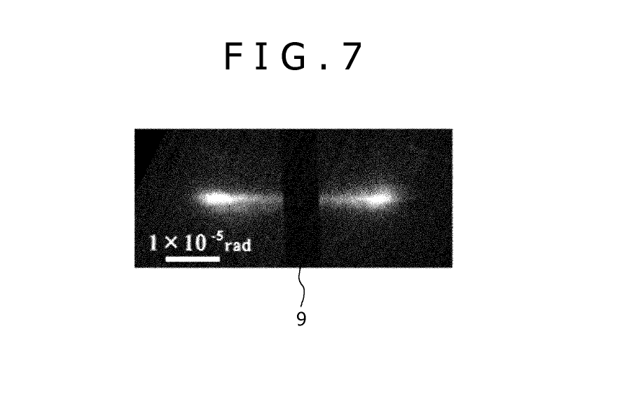

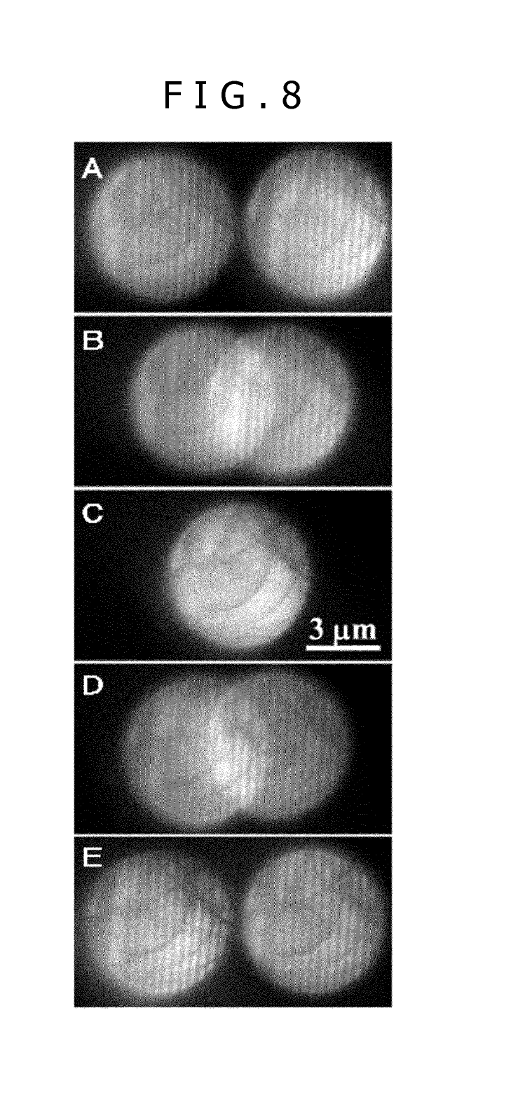

The experimental results are shown in FIG. 7 and FIG. 8. The sample is a material of manganese oxide and that is known to undergo a phase transformation when cooled that forms a 180 degree inverted magnetic domain structure. Observation is made by utilizing an electron microscope with an accelerating voltage of 300 kV and with the sample cooled to 106 K.

FIG. 7 is a light source image on the lower side of the objective lens. The light source image from deflection by the sample can be seen separated into two images. The contrast black belt in the center section between both light source images is an image of the center super-fine electrode 9 of the electron biprism. The electron beam does not transmit through this region, so this section is observed as a black silhouette. This electron biprism is inserted in the image surface of the light source directly below the objective lens.

FIG. 8 is an image of the sample observed when a voltage is applied to the electron biprism in the state shown in FIG. 7. In FIG. 8, A shows an observation image when −100 V was applied, B shows an observation image when −50 V was applied, C shows an observation image when 0 V was applied, D shows an observation image when +50 V was applied, and E shows an observation image when +100 V was applied. Viewing FIG. 8, A and E reveals that the vertical stripes are the contrast due to the magnetic domain structures, and C in FIG. 8 reveals that the curved stripe shapes are the contrast from the equal inclination fringe unique to the sample, etc.

Moreover, a CCD camera was utilized in the observation the magnification is adjusted so that two images can be recorded on one screen. Here, along with the application of voltage, one can see that the ordinary electron microscope image of C in FIG. 8 changes to a Foucault image due to the electron beam transmitted through the respective magnetic domains. The size of the voltage that is applied is dependent on the size of the observation region. Namely, the voltage to apply need only be large enough to sufficiently separate the regions for observation. Viewing FIG. 8, A and E reveals that the Foucault images have only been interchanged on the left and right so that the voltage to be applied can be either negative or positive. Needless to say, the voltage applied to the electron biprism is also dependent on the accelerating voltage of the electron beam.

As described above, the present invention can capture images under completely identical irradiation conditions, and also in which the electron beam is simultaneously deflected in two directions. The present invention can therefore of course make dynamic observations and real-time observations. Moreover, the observation in the image capture in FIG. 8 does not utilize an objective aperture and so can also perform high-resolution observations.

### Third Embodiment

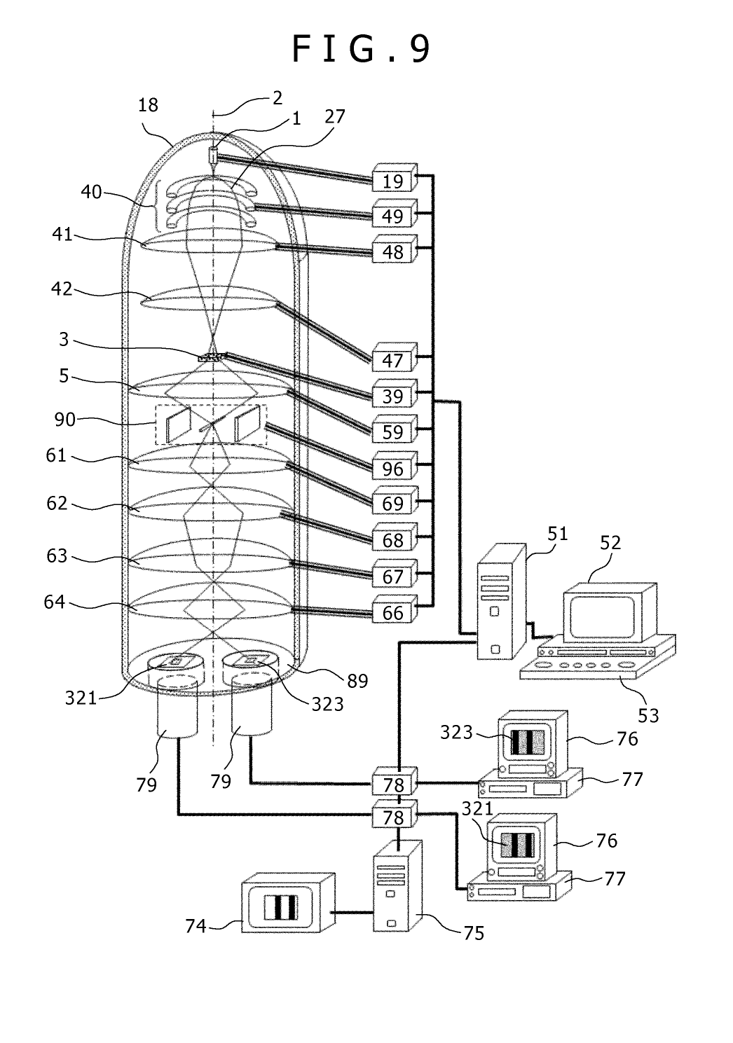

FIG. 9 is a diagram showing a typical structure of the electron microscope having the optical system for implementing the present invention. Here, an electron biprism 90 is mounted on the side below the objective lens 5 the same as in FIG. 6. Besides separately imaging the electron beams deflected in two directions, the two observation recording media 79 are mounted for the two images (321, 323).

In other words, the respectively separate images (321, 323) are recorded by way of TV cameras or CCD cameras whose sensitivity is separately adjusted so that the processing precision can easily be boosted in the subsequent arithmetic processing. FIG. 9 shows the state where the image data captured by the two observation recording media 79 are sent by way of the respective separate control units 78 to the arithmetic processor 75, and output to the display device 74 as one image data.

Even a processing system utilizing a conventional control unit 78, a data recording device 77, and an image display device 76 is capable of image operation processing, however in view of development potential for processing accuracy and for purposes of simplifying the description, the structure in the drawing employs a separate arithmetic processor 75 and its display device 74. However, the specification is not limited to this structure. Moreover, electron microscope photographic film was utilized in the related art as the observation recording medium 79, however in recent years TV cameras and CCD cameras have come into general use so an appropriate description is given. This specification is not limited in this respect also.

An example of the adjustment method for the two observation recording media 79 is described next.

### (1) Sensitivity Adjustment:

Even if utilizing the same type and model of recording medium, identical adjustments must be made to the brightness and the contrast of the image acquired in the recording system. Whereupon, the electron beam is widely and uniformly irradiated on the observation recording surface 89 in a state where the sample 3 and electron biprism 90 are not inserted on the optical axis 2, and the sensitivity is adjusted so that the same brightness on the two observation recording media 79 form the same input data. The control unit 78 and data recording device 77, and the display device 76 such as the monitor are simultaneously adjusted until this input data is output.

### (2) Electron Biprism Position Adjustment:

After the adjustment in the above (1), the sample 3 and electron biprism 90 are inserted on the optical axis 2, and the position and orientation of the center super-fine electrode are adjusted so that the center super-fine electrode for the electron biprism is between the two light source images and intersects with the line segments joining both light source images, while observing the light source images shown in FIG. 7. The image position, orientation, and magnification are next adjusted so that both images (321, 323) are observed.

Adjusting the orientation of the images (321, 323) and the observation recording medium 79 pivoting on the optical axis 2 can be accomplished by various methods including: (1) rotating the sample 3 around the optical axis 2 as a pivot; (2) rotating the electron biprism 90 around the optical axis 2 as the pivot; (3) adjusting by utilizing the image rotation effect of the magnetic field type imaging lenses (61, 62, 63, 64); and (4) rotating the observation recording medium 79 around the optical axis 2 as a pivot.

Currently, for the above method (2), the use of a rotating mechanism in the electron biprism 90 has become common. However, using this rotating mechanism requires aligning the center super-fine electrode of the electron biprism with the electron beam 27 deflection direction from the sample 3 so joint usage of another technique rather than just the method in (2) is required.

The above described adjustment of the observation recording medium 79 cannot only be performed at any time but also provides the advantage that differences in brightness and contrast of the two images (321, 323) due to some type of circumstances can be corrected during actual use not only on the electron optical system but also on the image processing device side. A further advantage is that along with storing the respective initial adjustment values as defaults at this time, the initial adjustment values can be restored whenever needed.

The example in FIG. 9 describes the electron biprism 90 and lenses (61, 62, 63, and 64) for an enlargement imaging system while assuming the electron microscope with accelerating voltage from the 100 kV to 300 kV of the related art, however the structural elements of the electron microscope optics system of the present invention are not limited to this example. Further, the actual device may include structural elements other than shown in FIG. 9, such as a deflection system to change the direction of electron beam progression, or an aperture mechanism for restricting the transmitting region of the electron beam.

However, these devices are not directly related to the present invention and are therefore omitted in FIG. 9. The electron optical system is assembled inside a vacuum container 18, and is continuously exhausted by a vacuum pump; however the vacuum exhaust system is not directly related to the present invention and is therefore omitted. These omitted portions are the same in the following drawings where necessary.

### Fourth Embodiment

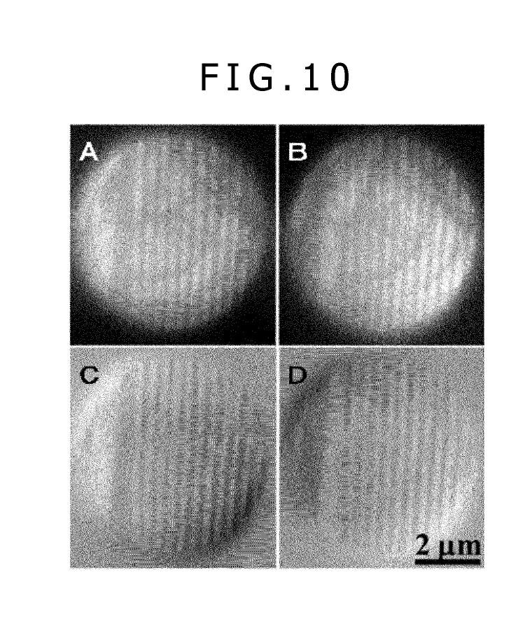

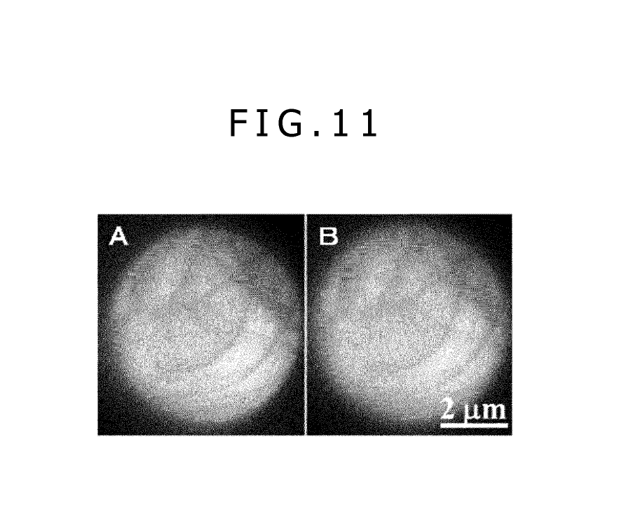

FIG. 10 and FIG. 11 show examples of arithmetic processing of the two image data that were obtained. Image data prior to processing is the experiment results of FIG. 8. Needless to say, the position of the sample of the respective image data is matched prior to the arithmetic processing. That method may for example utilize an image processing technique such as obtaining the correlation of the two images, and achieve position matching at a sub-pixel level that is approximately one-tenth of the pixel from the pixel level in the arithmetic processing.

A and B in FIG. 10 are two Foucault images from A in FIG. 8. The vertical stripes in the figure are contrast from magnetic domain structures, and the curved stripe shapes are the contrast due to equal inclination fringe. Comparing A with B in FIG. 10 shows that the magnetic domain contrast is inverted. C and D in FIG. 10 are the results from performing subtraction processing mutually from these two Foucault images.

In other words, C in FIG. 10 is the difference image that subtracts B from A in FIG. 10, and adjusting the brightness during the overall display so that image brightness (intensity) of zero forms a half tone. Contrary to C in FIG. 10, D in FIG. 10 is the difference image from subtracting A from B in FIG. 10. Comparing C with D in FIG. 10 clearly shows that the contrast of the magnetic domain is inverted.

Not only is the contrast of the magnetic domain structures inverted but C and D in FIG. 10 are both difference images so that patterns within the sample such as the equal inclination fringe unrelated to the magnetic domain structures forming the background of the entire image, are eliminated by subtraction processing, and images formed with magnetic domain structures emphasized more than FIG. 8. Namely, during observation of magnetic domain structures, the contrast such as from characteristic defects in samples with formed artifacts is eliminated. This subtraction processing is effective for high-accuracy, high-sensitivity observation of magnetic domain structures.

Another example of arithmetic processing is shown in FIG. 11. A in FIG. 11 is a normal electron microscope image, and is identical to C in FIG. 8. B in FIG. 11 is both images in A of FIG. 8 or namely, is an overlapping image where the images of A and B in FIG. 10 are summed together. Comparing A with B in FIG. 11 reveals that the curved stripe shapes match each other, and that both are the same image. In other words, the figures show that summing the respective Foucault images deflected in two directions obtains electron microscope images the same as in the related art. The present invention does not require additional tasks and their subsequent observation such as for shifting the electron biprism away from the optical axis or zeroing the voltage applied to the electron biprism in order to obtain an electron microscope image.

The above subtraction and summing processing of both images were effective under exactly the same irradiation conditions and also on Foucault images from electron beams deflected in two directions so that the brightness, contrast, noise, and background image of the sample and so on for both Foucault images were found to match with high accuracy. The present invention is clearly effective for arithmetic processing.

Besides arithmetic processing by this type of subtraction and addition of plural images, the present invention is also capable of implementing multiplication and division processing among plural images. Also, arithmetic processing implemented on each of the individual images such as summing and subtraction processing of the background (brightness adjustment of the entire image), multiplication and division processing of the background (contrast adjustment of the image) or multiplication and division processing based on functions (uniformity processing for brightness distribution) can be implemented by normal image arithmetic processing with no problems whatsoever. Further, among others, spatial frequency processing (high-pass filtering and low-pass filtering) by image blur filtering, and Fourier transform processing can also be implemented.

### Fifth Embodiment

The direction and orientation that the electron beam is deflected within the sample is not limited to only two directions. Even assuming that the sample has a comparatively simple inverse magnetic domain structure, the direction of the magnetic structures in that region can be changed if there is a region having a different crystalline orientation within the sample. If images can thereupon be obtained that are respectively dependent on the deflection direction and orientation of the electron beam by employing plural electron biprism, the structure within the sample can then be imaged in further detail.

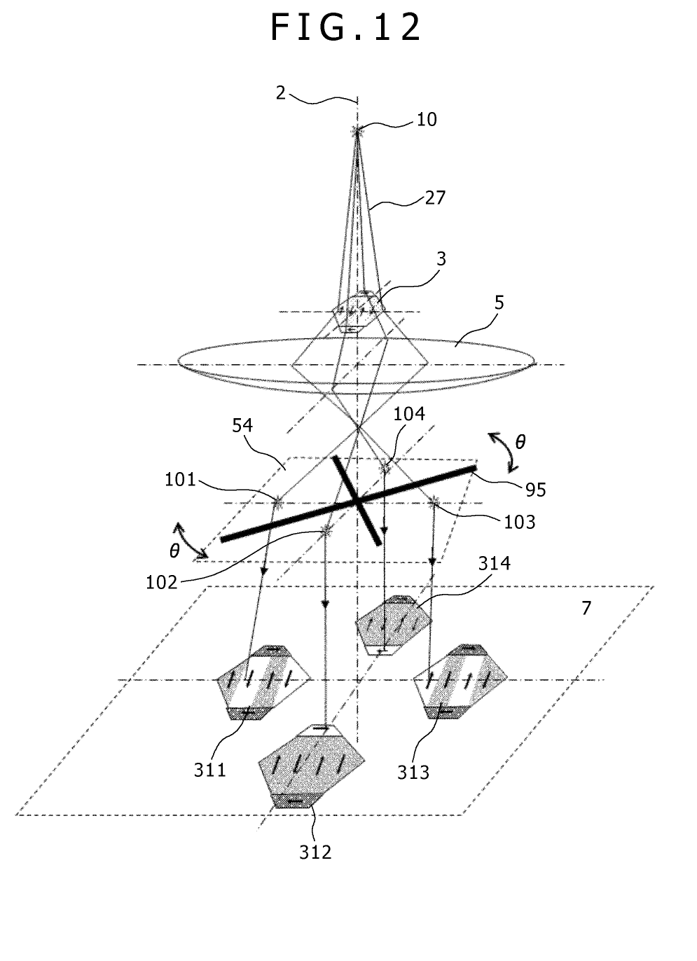

FIG. 12 shows a structural view when utilizing the square pyramidal electron prism 95. The square pyramidal electron prism is an electron biprism having two intersecting center super-fine electrodes as a so-called two-piece one-pair electron biprism, and contains the same optical elements as square pyramidal prism utilized in optics. There is no significant change in performance in electron beam deflection from that of an ordinary electron biprism even in the case that intersecting center super-fine electrodes are utilized. This structure (FIG. 12) is simpler than placing two electron biprisms in proximity and the same effect can be expected.

To simplify the description, only one path 27 is shown in FIG. 12 to represent the respective electron beam propagation. When there are regions within the sample deflecting the electron beam in four directions and orientations, the incident electron beam 27 is deflected in the four directions and orientations of the respective regions. This electron beam 27 is then deflected in the respective propagation directions by the square pyramidal electron prism 95 mounted in proximity to the image surface 54 of the light source on the lower side of the objective lens 5 completely the same as previously described, and the separate images (311, 312, 313, 314) are respectively imaged on the image surface 7.

Needless to say, in the present embodiment, the sample, square pyramidal electron prism, image rotation function by imaging lens, and observation recording systems may also be capable of rotating around the optical axis as a pivot, in order to adjust the positional relationship of the deflected electron beam, square pyramidal electron prism, and the observation recording media on the observation recording surface. Moreover, the square pyramidal electron prism 95 in FIG. 12 is mounted on the side below the objective lens 5, however the objective lens 5 may be substituted with any lens of the enlargement imaging system, and the square pyramidal electron prism may be substituted by plural electron biprisms that directly intersect in the shadow space of the deflected electron beam.

When at this time there are plural electron biprisms mounted by way of the electron lens, and the two upper/lower electron biprisms optically satisfy an equivalent relation by way of the intermediate electron lens (for example, relation between the object surface and image surface in the imaging optical system), the same effect is obtained as if there are two electron biprisms in the same space.

If the above described structure was also capable of utilizing many electron biprisms, the structure of internal portions of the sample or in other words, the deflection orientation of the electron beam within the sample can be imaged as a detailed distribution map. In particular, when the square pyramidal electron prism. 95 matches the image surface 54 of the light source, the adjustment of other elements in the optical system is not necessary if the each image can be recorded while the square pyramidal electron prism 95 is rotated a little at a time around the optical axis as the pivot, and the deflection orientation of the electron beam within the sample 3 can be imaged as a distribution map in more detail.

FIG. 12 shows the rotation in this direction by the arc-shaped arrows and the theta (θ) symbol. If the cause of electron beam deflection within the sample 3 is magnetism, the magnetic distribution within the sample can be imaged. If the cause is electrical charges then the electrical charge distribution of the inductor can be imaged. In either case, the electron beam deflection direction and its distribution mage can be imaged. However, an improvement in resolution and accuracy of the orientation distribution with the optical axis 2 as the origin point, and the size of the deflection angle of the electron beam from the sample are not limited to this description. To achieve this objective, imaging that corresponds to the axial separation distance from the optical axis is required, and techniques to accomplish this objective include joint usage of an objective aperture, etc.

If the square pyramidal electron prism 95 does not match the image surface 54 of the light source, each image (311, 312, 313, 314) will also rotate at that position, along with the rotation direction of the square pyramidal electron prism 95. In that case, the position of the observation recording medium 79 must also be shifted by rotation while linked with the rotation of the square pyramidal electron prism 95. However, this rotational shift may be omitted in cases where changes due to rotational shift are compensated by image processing, such as image data captured on a single image capture device.

### Sixth Embodiment

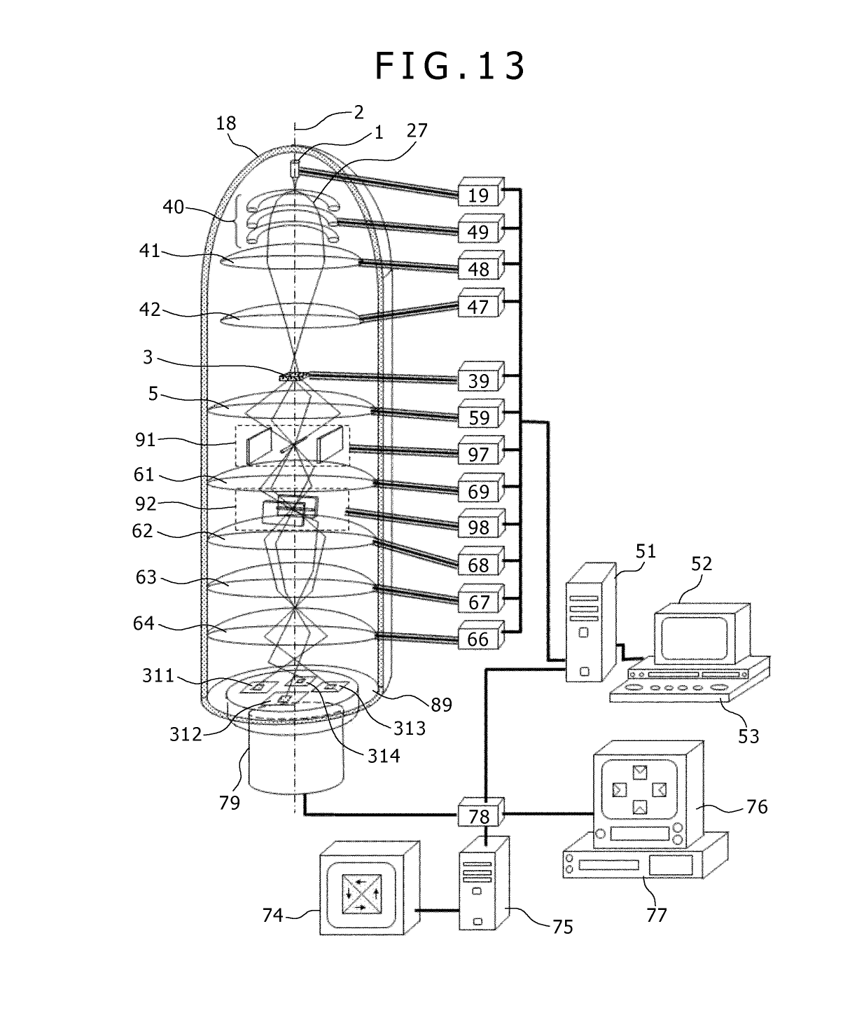

FIG. 13 is a drawing showing an example of the structure of an electron microscope including the optical system for implementing the present invention the same as in FIG. 9. The drawing shows an example of a device structure including an optical system mounted with plural electron biprisms by way of electron lenses described in the fifth embodiment. In other words, a first electron biprism 91 is mounted on the lower side of the objective lens 5; and the second electron biprism 92 is mounted on the lower side of the first imaging lens 61.

If the first electron biprism 91 is at the object surface position, and the second electron biprism 92 is at the image surface position, the positional relation is a totally equivalent relation excluding the optical magnification (scale). The magnification is also no problem whatsoever if set to magnification 1. The rotation of the first electron biprism image is added by way of the first imaging lens 61; however the orientation relation of the upper and lower electron biprisms can be selected to account for this rotation.

In the structure shown in FIG. 13 one observation recording medium 79 is utilized as the observation recording system. The experimental example (results in FIG. 8) shown in the second embodiment is a structure relating to the observation recording system. This type of structure may for example utilize a CCD camera with a large screen and large number of pixels. CCD devices currently mainly utilized 4096 pixels×4096 pixels but rapid advances are being constantly made the future usage of CCD devices with even larger screens and a larger number of pixels can easily be envisioned. If a pixel with one large screen and large number of pixels can be utilized, the task of adjusting the plural detectors described in the FIG. 9 would be unnecessary, and the effort in producing the present invention could be greatly alleviated. The effect rendered would also be the same in the other embodiments.

In the arithmetic processing described in the fourth embodiment, as can be seen in the experimental results in FIG. 8, the brightness of the image in the area where the image data is recorded is drastically different from the background so that the plural images can be easily separated and can be utilized along with subsequent arithmetic processing. Further, as shown in B and D of FIG. 8, if the range wanted for observation can be spatially isolated, that range can be extracted and utilized in subsequent arithmetic processing, even if the overall image has not been totally separated. Use of sample positions of the plural images required for the arithmetic processing can be achieved as described in the fourth embodiment.

### Seventh Embodiment

The description up until now mainly assumed usage of samples having magnetic materials with inverse magnetic domain structures. However, even in samples including electric potential distributions such as semiconductor elements and dielectric polarized structures such as dielectric materials, the dielectric polarization and electric potential distribution can be respectively imaged as the deflection direction of the electron beam the same as in magnetic domain structures.

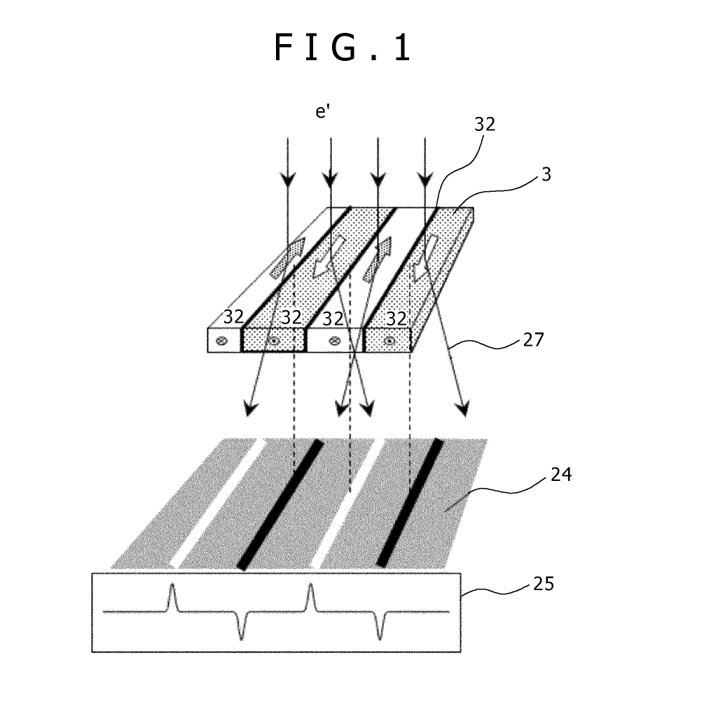

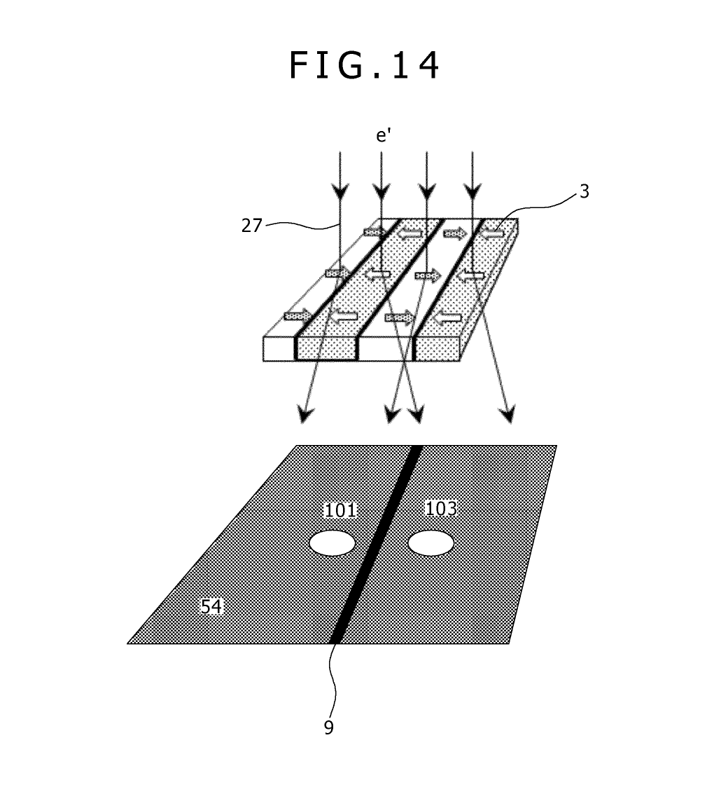

FIG. 14 is a diagram showing the concept for applying deflection by way of the electron biprism 9 and the state of deflection of the electron beam 27 in the dielectric material 3 containing polarized structures. However the crystalline structure in the dielectric material 3 can be ignored. The observation of the crystalline structure is described in the following eighth embodiment. When the sample 3 is a uniform thickness, the point where the electron beam transmitting through the sample is deflected at an angle equal to the intensity of the polarization, is the same as the case for magnetic material shown in FIG. 1.

The center super-fine electrode 9 for the electron biprism is mounted perpendicularly between the images (101, 103) of the two separate light sources, on the image surface 54 of the light source on the lower side of the objective lens. The contrast in the center of the image surface 54 of the light source shown in the lower section of FIG. 14 corresponds to the experimental results in FIG. 7. The correspondence is also the same in the subsequent figures. A completely identical observation technique can be implemented even when observing the charge distribution of inductors and so is called Lorentz electron microscopy regardless of the derivation of the name.

Namely, the same effect can be obtained while maintaining the technique for implementing the present invention, by utilizing a sample substituted with magnetic material or semiconductor elements.

### Eighth Embodiment

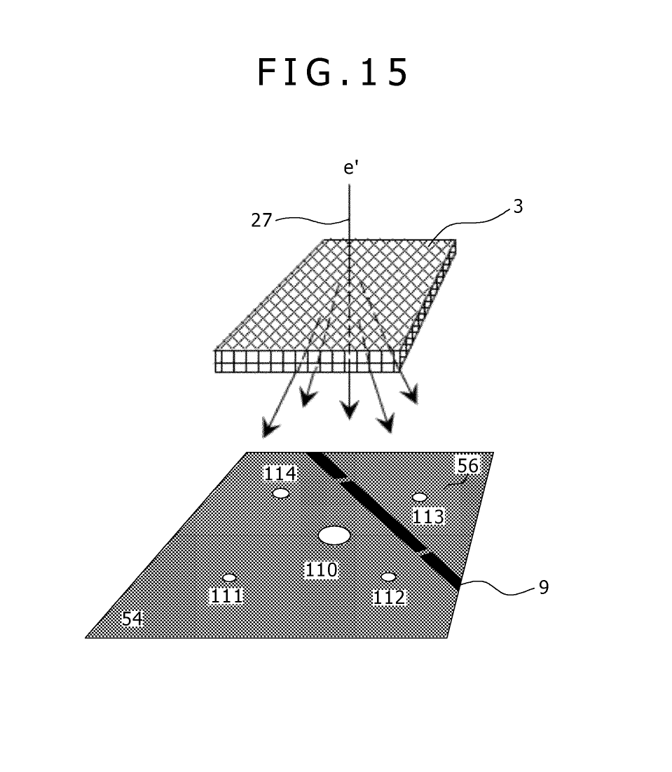

FIG. 15 shows an overview of how deflection is applied by the electron biprism 9 and the state of the Bragg diffraction of the electron beam in the sample 3 when observing the crystalline sample. During Bragg diffraction in the crystalline material, diffracted waves are generated in both positive and negative directions in the direction of the periodic structure according to the periodicity of the crystalline structure. FIG. 15 shows the state where symmetrical Bragg diffraction waves are being emitted four times along the center of the optical axis. The electron beam is transmitting unchanged through the sample 3 without being affected by diffraction so that five electron diffraction spots (110, 111, 112, 113, and 114) are formed on the image surface 54 of the light source.

FIG. 15 show a structure for example for performing simultaneous observation of an image (bright-field image: omitted from drawing) from a transmitted electron beam derived via the spot 110, and an image (dark-field image: omitted from drawing) from a diffraction electron beam via the spot 113. In other words, this method is capable of simultaneous observation of bright-fields and dark-fields. In the case of crystalline material, plural diffraction electron beams are emitted just as described above so that restrictions are required such as using an objective aperture when wanting to make a separate observation of just the diffraction electron beam. The white circle 56 in FIG. 15 is an image of the objective aperture hole utilized for implementing this restriction.

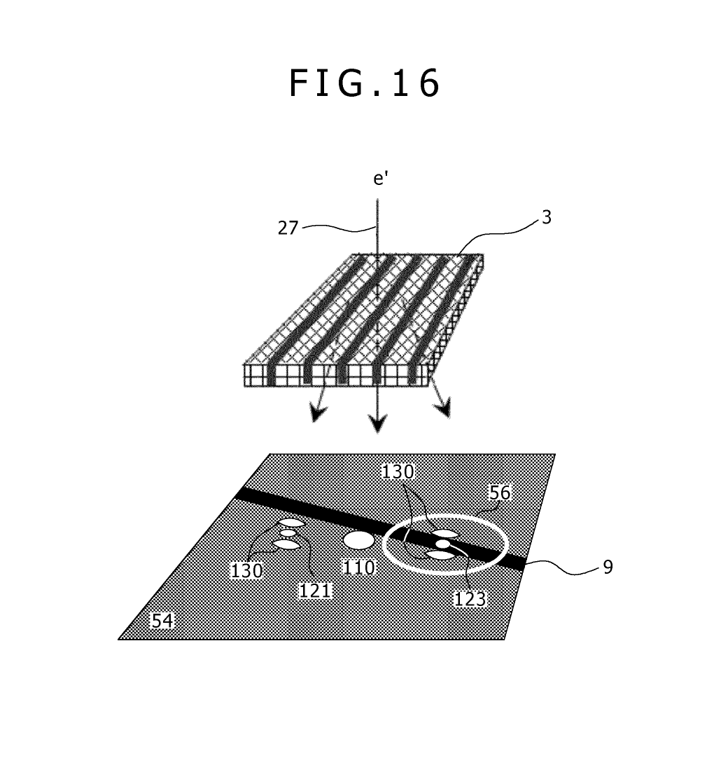

Though omitted from the drawing, the center super-fine electrode 9 for the electron biprism is jointly utilized as a beam stopper (see the ninth embodiment and FIG. 16) which for example blocks the transmitted electron beam and is capable of imaging observation which is two dark-field images via the diffraction electron beams on the left and right of the center super-fine electrode 9. Further, the present embodiment is capable of simultaneously observing four images among the bright-field images and dark-field images when using a square pyramidal electron prism or an electron biprism having two intersecting center super-fine electrodes just as in the fourth embodiment.

### Ninth Embodiment

The strain occurring in the crystalline sample due to a variety of circumstances such as at boundaries where different materials are in contact such as the boundary surface of electrode metal and silicon substrate of semiconductor elements, or crystalline grain boundaries, and further when a magnetic field has applied for example to magnetic material; that strain distribution is known to bring about a ripple effect on the overall material. The collective name for this phenomenon is called the strain field. This strain field applies a deflection though only a slight one to the electron beam, capable of being imaged by dark-field holography, etc.

FIG. 16 is a drawing broadly showing an example of diffraction image by an artificial super-lattice and how deflection is applied by the electron biprism 9. Bragg diffraction by the crystalline material forms a spot on a higher-order position separate from the optical axis and so is omitted. A contracted region 130 from diffraction waves is occurring due to a strain field in the vicinity of the two electron diffraction spots (121, 123) at the super-lattice on the image surface 54 of the light source. The center super-fine electrode 9 for the electron biprism is thereupon mounted in a shape to block the super-lattice diffraction spot 123, in an observation method that images the separate diffraction electron beams caused by the strain field in the vicinity of the super-lattice diffraction spot 123. The objective aperture hole 56 selects only the periphery of the specified super-lattice spot 123 the same as in FIG. 15.

Each embodiment of the present invention is applicable to electron microscopes and in a focused state is capable of dynamic observation and real-time observation in a state where the electron beam is deflected or diffracted across the entire observation surface within the sample. A deflection is then again applied to the electron beam deflected or diffracted by the sample, in each propagation direction of the deflected or diffracted electron beam by utilizing for example an electron biprism mounted in the space in the shadow of the electron beam such as an angular space of the electron optics, so that the respective electron beam can separately and simultaneously form images at different positions on the image surface of the electron optical system.

In this way, plural images can be separately and simultaneously observed on the observation recording surface according to the deflection state in the sample while in a focused state, and the complete deflection state of the electron beam can be imaged across the entire observation surface of the sample. There are also no spatial frequency restrictions from the objective aperture so that higher-resolution observation can also be performed than in the Foucault mode of the related art.

Other effects of the present invention are that there is no need for modifying or readjusting the optical system when acquiring plural images, and that since completely the same lens and deflector are utilized for the irradiation optical system and imaging systems, the disturbances due to noise applied to the plural acquired images such as jitter from the lens current or induction field are completely the same, and that artifacts are not prone to easily occur during image analysis.

A further another effect is that images are acquired at a full deflection angle so that not only can the distribution of deflection components be shown on the projection surface by image processing, but can also be easily utilized in image analysis of each image such as from difference images and combined images, that allow even more detailed observation.

### LIST OF REFERENCE SIGNS

1 . . . Light source of electron beam or electron gun
10 . . . Light source image of electron beam on the upper section of sample
11 . . . Light source image of electron beam or electron diffraction spot deflected to right direction on the paper surface by sample
13 . . . Light source image of electron beam or electron diffraction spot deflected to right direction on the paper surface by sample
101,102,103,104 . . . Each of light source image of electron beam or electron diffraction spot separated into four direction and orientation by the deflection during transmitting through sample
110 . . . Light source image of electron beam or electron diffraction spot transmitted through sample
111,112,113,114 . . . Each of light source image of electron beam or electron diffraction spot separated into four direction and orientation by the Bragg diffraction during transmitting through sample
121,123 . . . Each of light source image of electron beam or electron diffraction spot separated by super-lattice diffraction
130 . . . Electron diffraction spot by the stain field
18 . . . Vacuum container
19 . . . Control unit for electron source
2 . . . Optical axis
21 . . . Electron beam deflected in right direction on paper surface by sample
22 . . . Space in the shadow of electron beam
23 . . . Electron beam deflected in right direction on paper surface by sample
24 . . . Projection surface
25 . . . Intensity distribution of electron beam on projection surface
27 . . . Electron beam or track of electron beam
3 . . . Sample
31, 33 . . . Magnetic domain
32 . . . Magnetic domain wall
311,312,313,314 . . . Each of Foucault image divided in four images by deflection
321,323 . . . Each of Foucault image divided in two images by deflection
35 . . . Focus position in lower section of sample
36 . . . Focus position in upper section of sample
37 . . . Sample image from objective lens, control unit for the sample
39 . . . Control unit for the sample
4 . . . Irradiation lens
40 . . . Accelerating tube
41 . . . First irradiation lens
42 . . . Second irradiation lens
47 . . . Control unit for second irradiation lens
48 . . . Control unit for first irradiation lens
49 . . . Control unit for acceleration tube
5 . . . Objective lens
51 . . . Control system computer
52 . . . Monitor for control system computer
53 . . . Interface for control system computer
54 . . . Image surface of light source in lower section of objective lens
55 . . . Objective aperture
56 . . . Objective aperture hole
59 . . . Control unit for objective lens
6 . . . Imaging lens
61 . . . First imaging lens
62 . . . Second imaging lens
63 . . . Third imaging lens
64 . . . Fourth imaging lens
66 . . . Control unit for fourth imaging lens
67 . . . Control unit for third imaging lens
68 . . . Control unit for second imaging lens
69 . . . Control unit for first imaging lens
7 . . . Image surface of sample from objective lens
71, 73 . . . Image of magnetic field
72 . . . Image of magnetic domain wall
74, 76 . . . Image display device
75 . . . Processing unit
77 . . . Image recording device
78 . . . Control unit for observation recording medium
79 . . . Observation recording medium
89 . . . Observation recording surface
9 . . . Electron biprism or center super-fine electrode of electron biprism
90 . . . Electron biprism
91 . . . First electron biprism
92 . . . Second electron biprism
95 . . . Square pyramidal electron prism
96 . . . Control unit for electron biprism
97 . . . Control unit for first electron biprism
98 . . . Control unit for second electron biprism
99 . . . Parallel-plate grounded electrode

1. An electron microscope comprising:
a light source that generates an electron beam;
an irradiating optical system that irradiates a single electron beam emitted from the light source onto a sample;
an imaging lens system including an objective lens and plurality of lenses that form an image of the sample;
an electron biprism that deflects the electron beam in mutually different directions after transmitting through the sample, and is placed on the downstream side from the objective lens in the direction of electron beam travel and mounted in a space in the shadow of the electron beam generated by deflection or diffraction when the electron beam is transmitting through the sample on the electron beam path;
an observation recording surface on which an image of the sample isolated by the electron biprism is observed; and
an image recording device that records the isolated image of the sample.

2. The electron microscope according to claim 1, further comprising:
an arithmetic processing device that performs arithmetic processing to find the orientation distribution of the deflected electron beam, or the orientation distribution of the diffracted electron beam.

3. The electron microscope according to claim 1,
wherein the space in which the electron biprism is mounted is near the image surface of the light source from the objective lens.

4. The electron microscope according to claim 1,
wherein the image recording device is plural image recording devices that respectively record each of the images of the sample isolated by the electron biprism.

5. The electron microscope according to claim 4, further comprising:
an arithmetic processing device that performs arithmetic processing to find the orientation distribution of the deflected electron beam, or the orientation distribution of the diffracted electron beam.

6. A sample observation method utilizing an electron microscope including a light source that generates an electron beam, an irradiating optical system that irradiates a single electron beam emitted from the light source onto a sample, an imaging lens system including an objective lens and a plurality of lenses that form an image of the sample, an electron biprism mounted in a space on the downstream side in the direction of electron beam travel from the objective lens, an observation recording surface on which an image of the sample is observed, and an image recording device that records the isolated image of the sample,
the sample observation method comprising:
irradiating a single electron beam emitted from the light source onto the sample by the irradiating optical system;
deflecting the electron beams in mutually different directions after transmitting through the sample, by way of an electron biprism mounted in a space in the shadow of the electron beam generated along the path of the electron beam by irradiation on the sample;
performing observation of the image of the sample isolated by the electron biprism on the observation recording surface;
recording an image of the observed sample by the observation recording device; and
finding the orientation distribution of the deflected electron beam, or the orientation distribution of the diffracted electron beam within the sample by the electron microscope based on the recorded image of the sample.

7. The sample observation method according to claim 6,
wherein the deflection of the electron beam, or the diffraction of the electron beam is caused by the magnetization of the sample.

8. The sample observation method according to claim 6,
wherein the deflection of the electron beam, or the diffraction of the electron beam is caused by the electrical charge or electrical potential of the sample.

9. The sample observation method according to claim 6,
wherein the deflection of the electron beam, or the diffraction of the electron beam is caused by the Bragg diffraction of the sample.

10. The sample observation method according to claim 6,
wherein the deflection of the electron beam, or the diffraction of the electron beam is caused by the strain field of the crystal in the sample.
